(19) United States
(12) Patent Application Publication
(10) Pub. No.: US 2011/0068379 A1
(43) Pub. Date: Mar. 24, 2011

(54) METHOD OF MANUFACTURING SEMICONDUCTOR DEVICE

(75) Inventor: Dong Chul KOO, Seongnam (KR)

(73) Assignee: Hynix Semiconductor Inc., Icheon (KR)

(21) Appl. No.: 12/843,684

(22) Filed: Jul. 26, 2010

(30) Foreign Application Priority Data
Sep. 21, 2009 (KR) 10-2009-0088891

(51) Int. Cl. H01L 29/78; H01L 21/336

(52) U.S. Cl. 257/288; 438/300; 257/E29.255; 257/E21.409

(57) ABSTRACT

A gate pattern is formed on a semiconductor substrate. An interlayer insulating layer is formed on the semiconductor substrate and then etched by using a SEG mask to form a SEG contact formation region. An exposed portion of the semiconductor substrate in the SEG contact formation region is uniformly grown and a source/drain region is formed in a grown portion of the semiconductor substrate through an ion implantation process.

### CROSS-REFERENCES TO RELATED APPLICATION

Priority to Korean patent application number 10-2009-0088891, filed on Sep. 21, 2009, which is incorporated by reference in its entirety, is claimed.

### BACKGROUND OF THE INVENTION

The present invention relates to a method of manufacturing a semiconductor device, and more particularly, to a method of manufacturing a semiconductor device capable of growing a semiconductor substrate.

In general, semiconductor memory devices are storage elements which store information such as data and program instructions and are typically classified into dynamic random access memories (DRAM) and static random access memories (SRAM). Herein, the DRAM is a memory which reads information stored therein and stores information therein. The DRAM is capable of reading or writing information, but it is a volatile memory where the information stored therein is volatile if the information is not periodically rewritten within a constant period. Although the DRAM needs to be continuously refreshed, since the price per memory cell is cheaper and the integration degree is higher, the DRAM has been widely used as a larger capacity memory.

Herein, a metal-oxide semiconductor field effect transistor (Hereinafter, referred to as MOSFET) which is mainly used in memories such as DRAMs and logic devices has a channel structure formed by depositing a gate oxide layer, a gate polysilicon layer, a gate metal layer and a gate hard mask layer and etching the gate hard mask layer, the gate metal layer, the gate polysilicon layer and the gate oxide layer through a mask and etching process.

FIG. 1 is a sectional view illustrating a method of manufacturing a semiconductor device according to a prior art.

Referring to FIG. 1, a gate pattern 140 including a gate oxide layer (not shown), a gate polysilicon layer 110, a gate metal layer 120 and a gate hard mask layer 130 is formed on a semiconductor substrate 100. Next, gate spacers 145 are formed on sidewalls of the gate pattern 140. At this time, the gate spacers 145 are formed of a nitride layer.

Subsequently, an exposed portion of the semiconductor substrate 100 except for the gate pattern 140 is grown by a SEG (Silicon Epitaxial Growth) method to form a pattern (not shown) formed of a Si layer.

Next, a source/drain region 150 is formed by implanting impurities in the pattern.

Subsequently, interlayer insulating layers 160 and 170 are sequentially stacked on an entire resultant structure of the semiconductor substrate 100 including the source/drain region 150 and then etched to form a contact region (not shown).

Next, a barrier metal layer 180 and a metal layer 190 are buried within the contact region. Until the interlayer insulating layer 170 is exposed, the barrier metal layer 180 and the metal layer 190 are chemical mechanical polished to form a contact 200. At this time, the barrier metal layer 180 is formed of a stack structure of Ti and TiN and the metal layer 190 is formed of W. Next, a bit line 210 is formed to be connected to the contact 200.

In the prior art, the grown portion of the semiconductor substrate (that is the pattern grown by SEG) has a non-uniform shape. When the source/drain region is formed in the pattern having a lower height by implanting impurities, the impurities are implanted in a deep portion of the semiconductor substrate 100. Therefore, the semiconductor effective channel length (Leff) is reduced (see a region A of FIG. 1) as well as the source/drain region which is adjacent to the gate pattern 150 has a sloped side (Refer to a region B of FIG. 1). Furthermore, due to the difference of the growth height between the source and drain regions (see a region C of FIG. 1), it is impossible to ensure uniform properties of the transistor.

### SUMMARY

According to one aspect of an exemplary embodiment, a method of manufacturing a semiconductor device is provided. A gate pattern is formed on a semiconductor substrate. A first interlayer insulating layer is formed on an entire resultant of the semiconductor substrate and then is etched by using a SEG (silicon epitaxial growth) mask to form a SEG contact formation region. An exposed portion of the semiconductor substrate in the SEG contact formation region is grown. A source/drain region is formed in a grown portion of the semiconductor substrate through an ion implantation. A contact is formed to be contacted to the source/drain region.

The first interlayer insulating layer may be preferably comprised of a BPSG (boro-phospho-silicate glass) layer.

The forming the contact connected to the source/drain region may preferably include forming a second and a third interlayer insulating layers on an entire resultant of the semiconductor substrate including the gate pattern and the source/drain region, etching portions of the second and the third interlayer insulating layers until the source/drain region is exposed, and burying a conduction material within etched portions of the second and the third interlayer insulating layers.

The conduction layer may be preferably comprised of any one of TiN and TiN/W or a combination thereof.

The second interlayer insulating layer may be preferably comprised of a BPSG layer.

The third interlayer insulating layer may be preferably comprised of a SOD (silicon on dielectric) layer or a HDP (high density plasma) layer.

The SEG mask may preferably have a length and a width smaller than or equal to a length and a width of the gate pattern.

The grown portion of the semiconductor substrate may be preferably formed at a height of 10 Å to 1000 Å.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a sectional view illustrating a method of manufacturing semiconductor device.

FIGS. 2A to 2D are sectional views illustrating a method of manufacturing a semiconductor device according to an embodiment of the present invention.

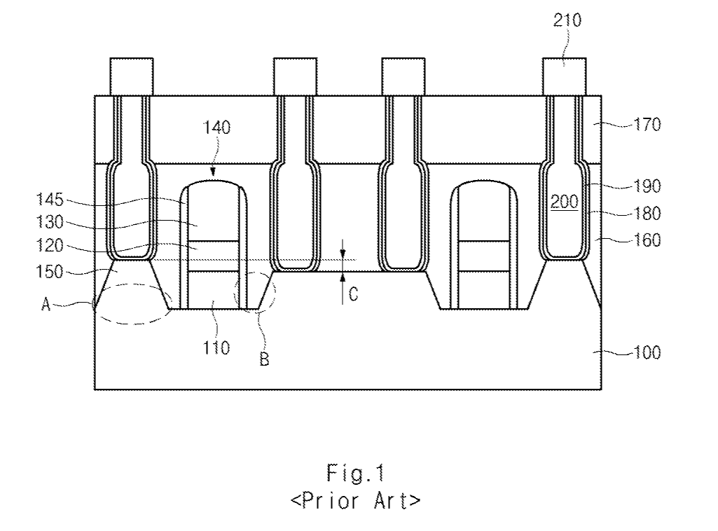

### DESCRIPTION OF EXEMPLARY EMBODIMENT

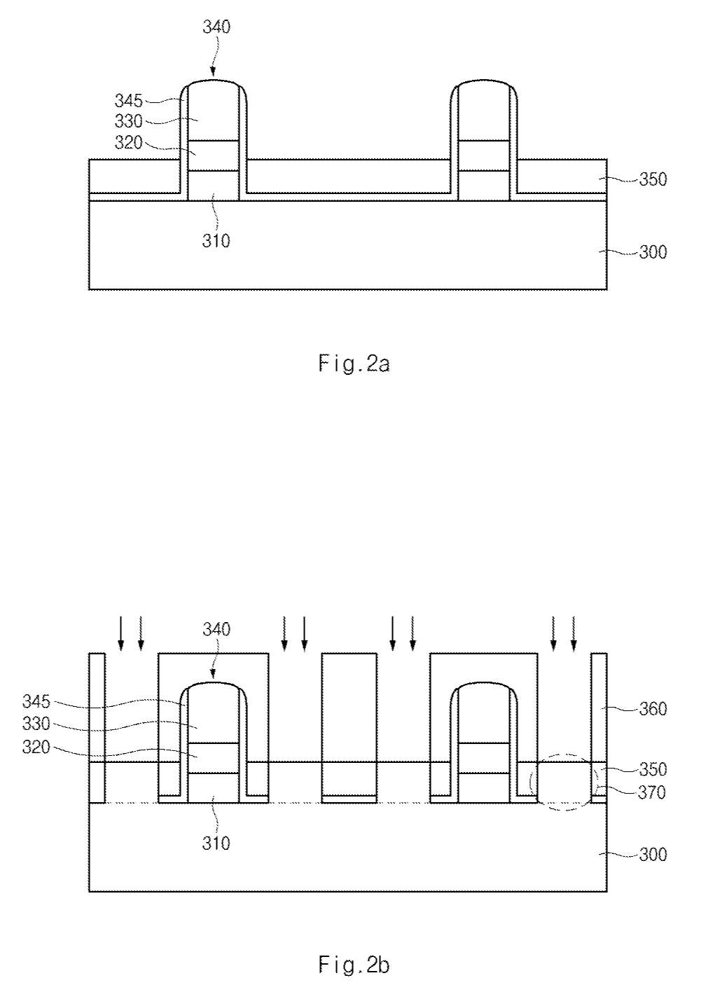

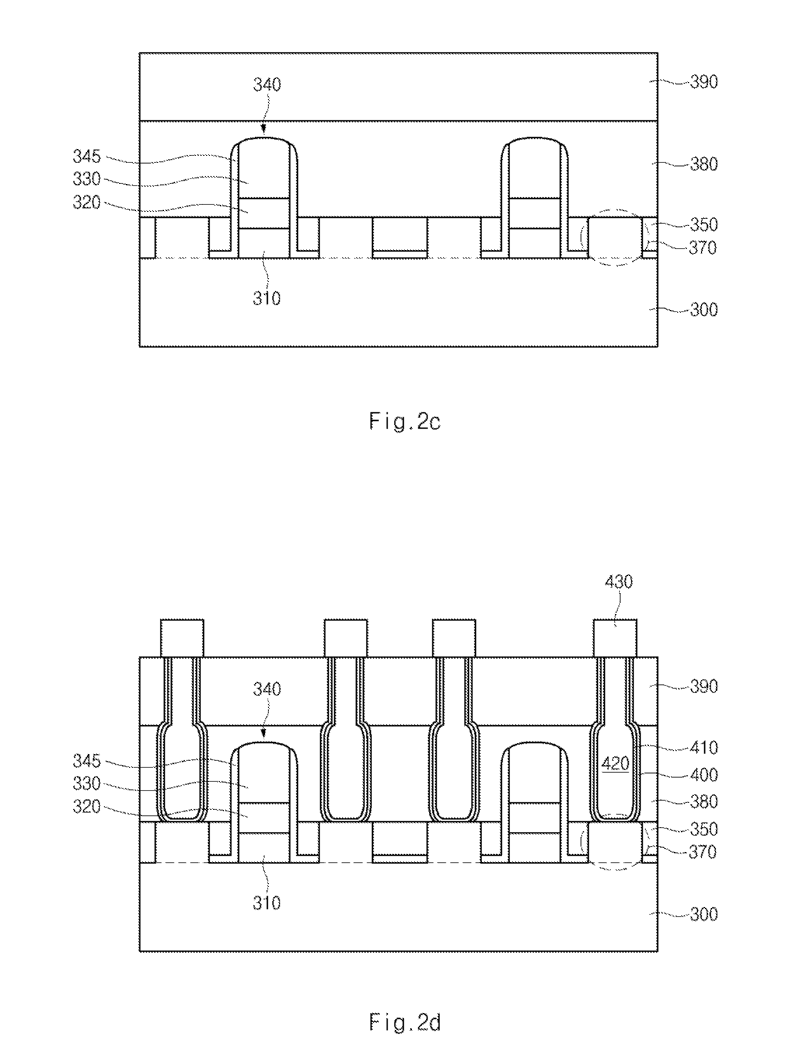

Embodiments are described herein with reference to FIGS. 2A to 2D. This invention is not limited to this embodiment but other variations are possible, for example, in manufacturing techniques and/or tolerances. Thus, embodiments disclosed herein should not be construed to limit the scope of this invention. In the drawings, lengths and sizes of layers and regions may be exaggerated for clarity. Like reference numerals in the drawings denote like elements. It is also understood that when a layer is referred to as being “on” another layer or a substrate, it can be directly on the other layer or the substrate, or indirectly formed thereon with intervening layers therebetween.

FIGS. 2A through 2D are sectional views illustrating a method of manufacturing a semiconductor device according to an embodiment of the inventive concept.

Referring to FIG. 2A, a gate pattern 340 including a gate oxide layer (not shown), a gate polysilicon layer 310, a gate metal layer 320 and a gate hard mask layer 330 is formed on a semiconductor substrate 300. Next, spacers 345 are formed on sidewalls of the gate pattern 340. At this time, the spacers 345 may be preferably comprised of a nitride layer and the spacers 345 may be extended to cover the semiconductor substrate 300.

Next, a first interlayer insulating layer 350 is formed on an entire resultant structure of the semiconductor substrate 300. The first interlayer insulating layer 350 may preferably be comprised of a Boro-Phospho-Silicate Glass (BPSG) layer. After forming the first interlayer insulating layer 350, a portion of the first interlayer insulating layer is etched until the gate pattern 340 is exposed.

Referring to FIG. 2B, a photoresist layer is formed on an entire resultant of the semiconductor substrate 300 including the first interlayer insulating layer 350 and patterned through an exposure and development process using a mask (not shown) defining a bit line contact hole to form a photoresist pattern 360. At this time, an open region made by the mask may preferably have a length and a width smaller than or equal to a length and a width of the gate pattern 340. Then, a SEG (Silicon Epitaxial Growth) process is performed using the photo resist pattern 360 as a mask to form an elevated SEG region. Owing to the elevated SEG region, a lengthy semiconductor effective channel length can be obtained and thus uniform properties of a resulting transistor can be obtained.

Specifically, the first interlayer insulating layer 350 is etched by using the photoresist pattern 360 as a mask until semiconductor substrate 300 is exposed to form a SEG contact formation region (not shown).

Subsequently, the semiconductor substrate 300 exposed by the SEG contact formation region is subject to a SEG process to form an elevated SEG pattern (not shown) formed of Si. At this time, the elevated SEG pattern can ensure a sufficient margin between the pattern and a contact to be formed in the following contact formation process. Furthermore, the first interlayer insulating layer 350 turns into a sidewall of the elevated SEG pattern, and thus a non-slant SEG pattern can be obtained.

Next, impurities are implanted into the elevated SEG pattern (not shown) to form a source/drain region 370. Subsequently, the photoresist pattern 360 is removed.

Referring to FIG. 2C, a second and a third interlayer insulating layers 380 and 390 are sequentially stacked on an entire resultant structure of the semiconductor substrate including the source/drain region 370. At this time, the second interlayer insulating layer 380 may preferably be formed of a BPSG layer and the third interlayer insulating layer 390 may preferably be formed of a SOD (silicon on dielectric) layer or a HDP (high density plasma) layer.

Referring to FIG. 2D, a photoresist layer is formed on the third interlayer insulating layer 390 and then patterned through an exposure and development process using a contact mask to form a photoresist pattern (not shown). The third and the second interlayer insulating layers 390 and 380 are etched by using the photoresist pattern as a mask until the source/drain region 370 is exposed to form a contact region (not shown)

Next, a barrier metal layer 400 and a metal layer 410 fill the contact region and then are subject to a chemical mechanical polishing process until the third interlayer insulating layer 390 is exposed, thereby forming a contact pattern 420. At this time, the barrier metal layer 400 may be preferably formed of a stack structure of Ti and TiN and the metal layer 410 may be preferably comprised of W. Next, a conductive pattern 430 is formed to be contacted to the contact pattern 420. The conductive pattern 430 may serve as a bit line pattern or a storage node pattern.

As described above, in the embodiments of the present invention, a gate pattern is formed on a semiconductor substrate, and an interlayer insulating layer is formed on the semiconductor substrate and then etched by using a SEG mask to form a SEG formation region, and an exposed portion of the semiconductor substrate in the SEG formation region is uniformly grown. Next, impurities are implanted into the grown portion of the semiconductor substrate to form a source/drain region. Therefore, reduction in the effective channel length and the slope of the source/drain region can be prevented and the properties of the transistor can be improved.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method of manufacturing a semiconductor device, comprising:
forming a gate pattern over a semiconductor substrate;
forming a first interlayer insulating layer on an entire resultant of the semiconductor substrate;
etching the first interlayer insulating layer to expose the substrate to form a contact region;
growing silicon on the exposed semiconductor substrate in the contact region to form an SEG pattern;
implanting ions into in the SEG pattern to form a source/drain region; and
forming a contact pattern electrically coupled to the source/drain region.

2. The method of claim 1, wherein the first interlayer insulating layer comprises a boro-phospho-silicate glass (BPSG) layer.

3. The method of claim 1, wherein the forming the contact connected to the source/drain region includes:
forming a second interlayer insulating layer and a third interlayer insulating layer over the semiconductor substrate including the gate pattern and the source/drain region;
etching portions of the second and the third interlayer insulating layers at least until the source/drain region is exposed; and
providing a conduction material within etched portions of the second and third interlayer insulating layers.

4. The method of claim 3, wherein the conduction material comprises any one of titanium(Ti), tantallium(Ta), titanium nitride (TiN), tantallium nitride(TaN), tungsten nitride(WN), stacking the titanium nitride (TiN) and tungsten (W) or a combination thereof.

5. The method of claim 3, wherein the second interlayer insulating layer comprises a boro-phospho-silicate glass (BPSG) layer.

6. The method of claim 3, wherein the third interlayer insulating layer comprises a silicon on dielectric(SOD) layer or a high density plasma(HDP) layer.

7. The method of claim 1, wherein silicon is grown on the exposed semiconductor substrate to a thickness of 10 Å to 1000 Å.

8. A method of manufacturing a semiconductor device, comprising:
forming a gate pattern over a semiconductor substrate;
forming an elevated silicon epitaxial growth (SEG) pattern over the semiconductor substrate between the gate patterns; and
forming a source/drain region in the SEG pattern,
wherein the elevated SEG pattern has a substantially vertical sidewall.

9. The method of claim 8, wherein the step of forming the elevated SEG pattern comprises:
forming an insulating layer over the substrate between the gate pattern;
patterning the insulating layer to form a contact hole exposing the substrate; and
growing silicon on the substrate exposed by the contact hole.

10. The method of claim 8, further comprising:
forming a conductive pattern electrically coupled to the source/drain region.

11. A semiconductor device, comprising:
a gate pattern formed over a semiconductor substrate;
an elevated silicon epitaxial growth (SEG) pattern formed over the semiconductor substrate between the gate patterns; and
a source/drain region formed in the SEG pattern,
wherein the elevated SEG pattern has a substantially vertical sidewall.

12. The semiconductor device of claim 11, further comprising:
a first insulating pattern formed between the two neighboring elevated SEG patterns to electrically insulate neighboring the elevated SEG patterns; and
a second insulating pattern formed between the SEG pattern and the gate pattern to electrically insulate the SEG pattern and the gate pattern.

13. The semiconductor device of claim 11, further comprising:
a conductive pattern electrically coupled to the source/drain region.

14. The semiconductor device of claim 13, wherein the conductive pattern is a bit line pattern or a storage node pattern.
